(19) United States
(12) Patent Application Publication
(10) Pub. No.: US 2011/0044113 A1
(43) Pub. Date: Feb. 24, 2011

(54) NONVOLATILE MEMORY DEVICE, METHOD FOR PROGRAMMING SAME, AND MEMORY SYSTEM INCORPORATING SAME

(75) Inventors: In-Mo KIM, Hwaseong-si (KR); Jae Yong JEONG, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/828,480

(22) Filed: Jul. 1, 2010

(30) Foreign Application Priority Data
Aug. 18, 2009 (KR) 10-2009-0076375

(51) Int. Cl. G11C 16/04

(52) U.S. Cl. 365/185.19; 365/185.18; 365/185.03

(57) ABSTRACT

A nonvolatile memory device performs a program operation on selected memory cells by determining a level of a program voltage based on a degree of deterioration of the memory cells, and executing the program operation using the program voltage.

### CROSS-REFERENCE TO RELATED APPLICATIONS

This application claims priority under 35 U.S.C. §119 to Korean Patent Application No. 10-2009-0076375 filed on Aug. 18, 2009, the disclosure of which is hereby incorporated by reference in its entirety.

### BACKGROUND

Embodiments of the inventive concept relate generally to semiconductor memory devices. More particularly, embodiments of the inventive concept relate to nonvolatile memory devices, methods for programming the nonvolatile memory devices, and memory systems incorporating the nonvolatile memory devices.

Semiconductor memory devices can be roughly divided into two categories based on whether they retain stored data when disconnected from power. These categories include volatile memory devices, which lose stored data when disconnected from power, and nonvolatile memory devices, which retain stored data when disconnected from power. Because nonvolatile memory devices retain stored data when disconnected from power, they are often used to store data that must be retained even when devices are powered down.

Examples of volatile memory devices include dynamic random access memory (DRAM) and static random access memory (SRAM). Examples of nonvolatile memory devices include electrically erasable programmable read only memory (EEPROM), ferroelectric random access memory (FRAM), phase-change random access memory (PRAM), magnetoresistive random access memory (MRAM), and flash memory.

In recent years, there has been an increase in the number of devices employing nonvolatile memory devices. As examples, nonvolatile memory devices are now used increasingly in MP3 players, digital cameras, cellular phones, camcorders, flash cards, solid state drives (SSDs), to name but a few. In addition, there has also been an increase in the overall storage capacity of nonvolatile memory devices, resulting in a tremendous amount of nonvolatile data storage in use today.

Flash memory is among the more frequently adopted forms of nonvolatile memory. It can be found in a wide variety of devices, including standalone applications such as memory cards, portable devices such as netbook computers, home electronics such as televisions, and others.

As flash memory continues to be adopted in a variety of devices, there is increasing pressure to improve the integration density of flash memories to provide larger storage capacity. To improve the integration density while retaining adequate performance and reliability, however, improvements are needed in various aspects of flash memory design and operation.

### SUMMARY

Embodiments of the inventive concept provide nonvolatile memory devices, methods for programming the nonvolatile memory devices, and memory systems incorporating the nonvolatile memory devices. In some embodiments, the method comprises adjusting a program voltage based on the degree of deterioration in selected memory cells and executing a program operation using the adjusted program voltage.

According to an embodiment of the inventive concept, a method of performing a program operation on memory cells in a nonvolatile memory device comprises determining a level of a program voltage based on a degree of deterioration of the memory cells, and executing the program operation using the program voltage.

In certain embodiments, the degree of deterioration is determined based on a number of program or erase cycles performed on the memory cells.

In certain embodiments, the degree of deterioration is detected based on a number of program and erase cycles performed on the memory cells.

In certain embodiments, determining the level of the program voltage comprises adjusting an increment of the program voltage to be applied between successive program loops of the program operation.

In certain embodiments, the method further comprises determining a level of a verify voltage for the program operation based on the increment of the program voltage.

In certain embodiments, the method further comprises determining a number of program or erase cycles performed on the memory cells, setting the increment of the program voltage to a first value upon determining that the number of program or erase cycles is greater than a predetermined value, and setting the increment of the program voltage to a second value greater than the first value upon determining that the number of program or erase cycles is less than or equal to the predetermined value.

In certain embodiments, the method further comprises setting a verify voltage for the program operation to a first level where the increment of the program voltage is set to the first value, and setting the verify voltage to a second level lower than the first level where the increment of the program voltage is set to the second value.

In certain embodiments, the program operation is executed with a high voltage received from an external source depending on the degree of deterioration of the memory cells.

In certain embodiments, the nonvolatile memory device is a multi-level cell flash memory device.

In certain embodiments, the program operation is executed using incremental step pulse programming.

According to another embodiment of the inventive concept, a nonvolatile memory device comprises a memory cell array, a read/write circuit configured to perform program and read operations on the memory cell array, a voltage generator configured to provide voltages to the memory cell array, and control logic configured to control the read/write circuit and the voltage generator. The control logic controls the voltage generator to adjust a program voltage depending on a degree of deterioration of memory cells in the memory cell array.

In certain embodiments, the degree of deterioration of the memory cells is detected based on a number of program and erase cycles that have been performed on the memory cells.

In certain embodiments, the control logic stores the number of program and erase cycles that have been performed on the memory cells.

In certain embodiments, the control logic is configured to program the memory cells using an acceleration mode wherein a high voltage supplied from an external source is provided to the memory cell based on the degree of deterioration of the memory cells.

In certain embodiments, the control logic controls the read/write circuit to perform a program operation using incremental step pulse programming with the adjusted program voltage.

In certain embodiments, the adjusted program voltage is incremented with a first or second increment in successive program loops of the program operation depending on a number of program or erase cycles that have been performed previously on the memory cells.

In certain embodiments, the memory cell array comprises flash memory cells arranged in a NAND flash configuration.

According to another embodiment of the inventive concept, a memory system comprises a nonvolatile memory device and a controller configured to control the nonvolatile memory device. The nonvolatile memory device comprises a memory cell array, a read/write circuit configured to perform read and write operations on the memory cell array, a voltage generator configured to provide voltages to the memory cell array, and control logic configured to control the read and write circuit and the voltage generator. The control logic controls the voltage generator such that a program voltage is adjusted depending on a degree of deterioration of memory cells of the memory cell array.

In certain embodiments, the nonvolatile memory device and the controller are incorporated in a solid-state drive.

In certain embodiments, the control logic controls the voltage generator to adjust a program verify voltage based on a number of program or erase operations that have been performed previously on selected memory cells to be programmed in a program operation.

### BRIEF DESCRIPTION OF THE DRAWINGS

Embodiments of the inventive concept are described below with reference to the accompanying drawings. In the drawings, like reference numbers denote like features.

FIG. 1 is a block diagram of a memory system according to an embodiment of the inventive concept.

FIG. 2 is a block diagram illustrating an example of a flash memory device shown in FIG. 1.

FIG. 3 illustrates a threshold voltage distribution of memory cells of the flash memory device shown in FIG. 2.

FIG. 4 illustrates a normal program operation of the flash memory device shown in FIG. 2.

FIG. 5 illustrates a fast program operation of the flash memory device shown in FIG. 2.

FIG. 6 is a block diagram illustrating an example of a program voltage generator of the flash memory device shown in FIG. 2.

FIG. 7 is a flowchart illustrating a program operation of the flash memory device shown in FIG. 2.

FIG. 8 is a block diagram illustrating an alternative embodiment of the flash memory device shown in FIG. 1.

FIG. 9 illustrates a threshold voltage distribution of memory cells programmed by the flash memory device shown in FIG. 8.

FIG. 10 illustrates a fast program operation of the flash memory device shown in FIG. 10.

FIG. 11 illustrates threshold voltage distribution of memory cells programmed by the flash memory device shown in FIG. 8.

FIG. 12 is a flowchart illustrating a program operation of the flash memory device shown in FIG. 8.

FIG. 13 is a block diagram illustrating another alternative embodiment of the flash memory device shown in FIG. 1.

FIG. 14 is a block diagram illustrating an alternative embodiment of the memory system shown in FIG. 1.

FIG. 15 is a block diagram illustrating a computing system incorporating the memory system shown in FIG. 2.

### DETAILED DESCRIPTION OF THE EMBODIMENTS

Selected embodiments of the inventive concept are described below with reference to the accompanying drawings. These embodiments are presented as teaching examples and should not be interpreted to limit the scope of the inventive concept as defined by the claims.

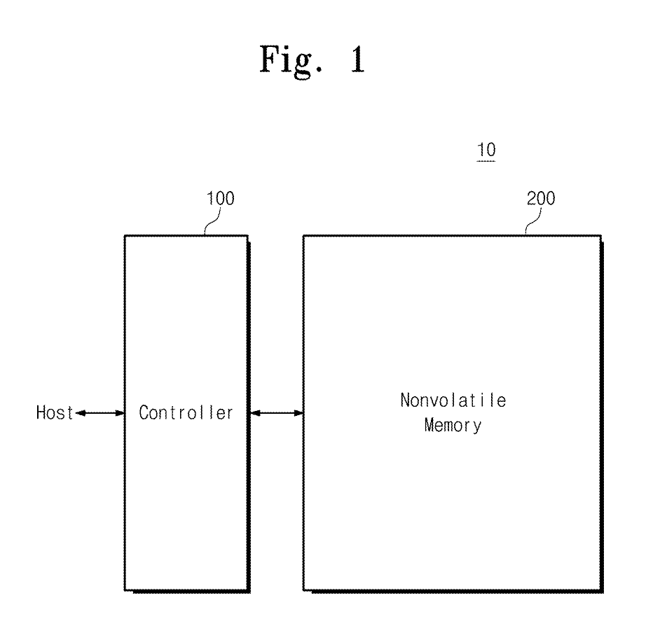

FIG. 1 is a block diagram of a memory system 10 according to an embodiment of the inventive concept. As illustrated, memory system 10 comprises a controller 100 and a nonvolatile memory device 200, also referred to as flash memory device 200.

Controller 100 is connected to a host and flash memory device 200. Controller 100 is configured to access nonvolatile memory device 200 in response to a request from the host. For example, controller 100 is configured to control read, write, and erase operations of nonvolatile memory device 200. Controller 100 is configured to provide an interface between nonvolatile memory device 200 and the host. Controller 100 is configured to drive firmware for controlling nonvolatile memory device 200.

Controller 100 typically comprises elements such as a random access memory (RAM), a processing unit, a host interface, and a memory interface. The RAM can be used as an operating memory of the processing unit, and the processing unit can control the overall operation of controller 100.

The host interface implements a protocol for data exchange between the host and controller 100. In certain embodiments, controller 100 is configured to communicate with an external entity (host) through one of various existing interface protocols such as a universal serial bus (USB) protocol, a multimedia card (MMC) protocol, a peripheral component interconnection (PCI) protocol, PCI-express (PCI-E) protocol, an advance technology attachment (ATA) protocol, a serial-ATA, a parallel-ATA protocol, a small computer small interface (SCSI) protocol, an enhanced small disk interface (ESDI) protocol, and an integrated drive electronics (IDE) protocol. The memory interface interfaces with nonvolatile memory device 200.

In some embodiments, controller 100 further comprises an error correction code (ECC) block for detecting and correcting any errors in data read from nonvolatile memory device 200. In certain embodiments, the ECC block forms part of controller 100 or nonvolatile memory device 200.

In some embodiments, controller 100 and nonvolatile memory device 200 are integrated into a single semiconductor device. For instance, controller 100 and nonvolatile memory device 200 can be integrated into one semiconductor device to form a memory card. As examples, controller 100 and nonvolatile memory device 200 can be integrated into one semiconductor device to form a PC card, a compact flash (CF) card, a smart media card (SM/SMC), a memory stick, a multimedia card (MMC, RS-MMC, MMCmicro), an SD card (SD, miniSD, microSD), or a universal flash memory device (UFS).

In certain embodiments, controller 100 and nonvolatile memory device 200 are integrated into one semiconductor device to form an SSD. Where memory system 10 is used as an SSD, the operation speed of a host connected to memory system 10 can be improved dramatically.

In various alternative embodiments, memory system 10 can be incorporated in devices such as a computer, a portable computer, a ultra mobile PC (UMPC), a workstation, a net-book, a PDA, a wet tablet, a wireless phone, a mobile phone, a smart phone, a digital camera, a digital audio recorder/player, a digital picture/video recorder/player, an apparatus for transmitting and receiving information in a wireless environment, one of various electronic devices in a home network, one of various electronic devices in a computer network, one of various electronic devices in a telematics network or one of various electronic devices forming part of a computing system, such as an SSD or a memory card.

Nonvolatile memory device 200 or memory system 10 can be mounted in various types of packages. For instance, nonvolatile memory device 200 or memory system 10 can be mounted in a package having one of the following configurations: package on package (PoP), ball grid array (BGA), chip scale packages (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline (SOIC), shrink small outline package (SSOP), thin small outline (TSOP), thin quad flatpack (TQFP), system in package (SIP), multi chip package (MCP), wafer-level fabricated package (WFP), and wafer-level processed stack package (WSP).

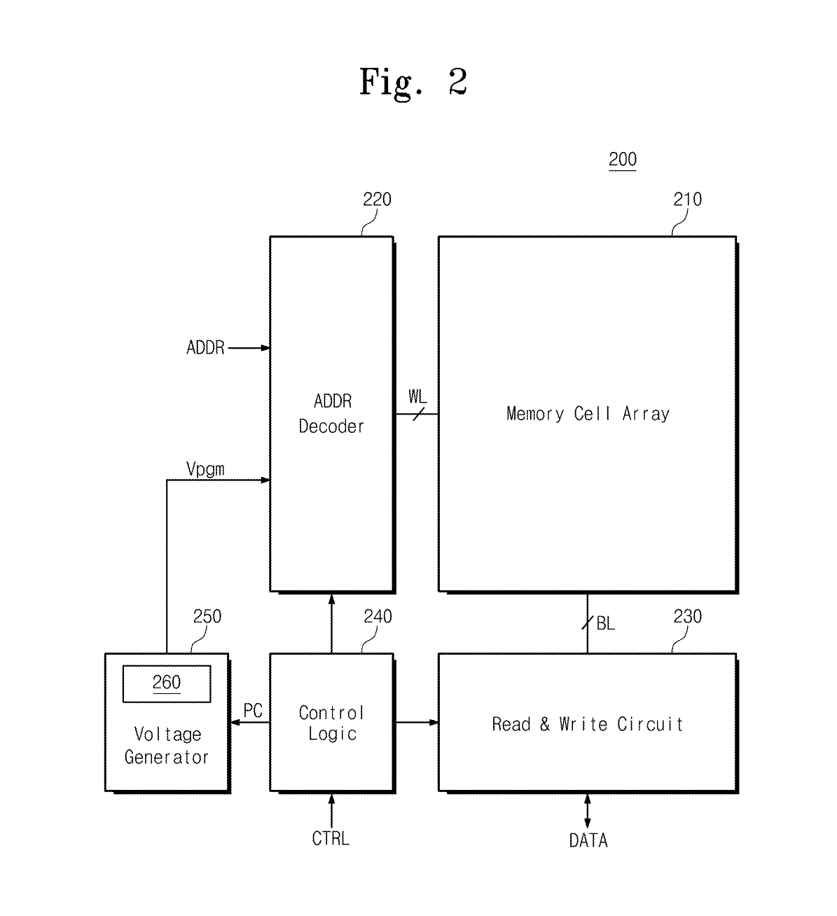

FIG. 2 is a block diagram illustrating an example embodiment of flash memory device 200 shown in FIG. 1. In the embodiment of FIG. 2, flash memory device 200 comprises a memory cell array 210, an address decoder 220, a read and write circuit 230, control logic 240, and a voltage generator 250.

Memory cell array 210 comprises a plurality of memory cells and is connected to address decoder 220 via wordlines WL and connected to read and write circuit 230 via bitlines BL. The memory cells of memory cell array 210 are typically arranged in rows connected to wordlines WL and column connected to bitlines BL. The memory cells can be configured to store one or more bits of data each.

Address decoder 220 is connected to memory cell array 210 via wordlines WL. Address decoder 220 operates in compliance with instructions from control logic 240. Address decoder 220 externally receives an address ADDR from a device such as controller 100 shown in FIG. 1.

Address decoder 220 decodes a row address and a column address from address ADDR. Address decoder 220 selects wordlines WL based on the decoded row address and transfers the decoded column address to read and write circuit 230 to select bitlines BL. Address decoder 220 typically comprises elements such as a row decoder, a column decoder, and an address buffer.

Read and write circuit 230 is connected to memory cell array 210 via bitlines BL. Read and write circuit 230 operates in compliance with instructions from control logic 240. Read and write circuit 230 is configured to exchange data with an external device. In certain embodiments, read and write circuit 230 exchanges data DATA with controller 100 shown in FIG. 1.

Read and write circuit 230 programs received data into memory cell array 210, and reads data out of memory cell array 210 and outputs the data to an external device. Read and write circuit 230 can also perform a copy-back operation by reading data out of a first storage area of memory cell array 210 and writing the read-out data into a second storage area of memory cell array 210.

In certain embodiments, read and write circuit 230 comprises elements such as a page buffer, a column selection circuit, and a data buffer. Read and write circuit 230 can also comprises elements such as a sense amplifier, a write driver, a column selection circuit, and a data buffer.

Control logic 240 is connected to address decoder 220, read and write circuit 230, and voltage generator 250. Control logic 240 is configured to control the overall operation of flash memory device 200. Control logic 240 operates in response to a control signal CTRL received from another device, such as controller 100 shown in FIG. 1.

Voltage generator 250 is configured to operate in compliance with instructions from control logic 240. Voltage generator 250 generates voltages of various levels used by flash memory device 200. For instance, voltage generator 250 typically generates a program voltage Vpgm, a verify voltage, a pass voltage, a read voltage, a select read voltage, an erase voltage, a bitline voltage, and a wordline voltage. The generated voltages are provided to various parts of flash memory device 200 depending on operations being performed. For instance, in a read and write operations, certain bias voltages are applied to wordlines WL via address decoder 220, such as a program voltage Vpgm, a verify voltage, a pass voltage, a read voltage, a select read voltage, an erase voltage, or a bitline voltage. Similarly, certain bias voltages can be applied to bitlines BL through read and write circuit 230, such as a power supply voltage, a ground voltage, and a bitline voltage. An erase voltage is typically provided to a bulk area of memory cell array 210.

Voltage generator 250 comprises a program voltage generator 260 configured to generate a program voltage in response to a program control signal PC provided from control logic 240. In certain embodiments, program voltage generator 260 is configured to control a level of program voltage Vpgm.

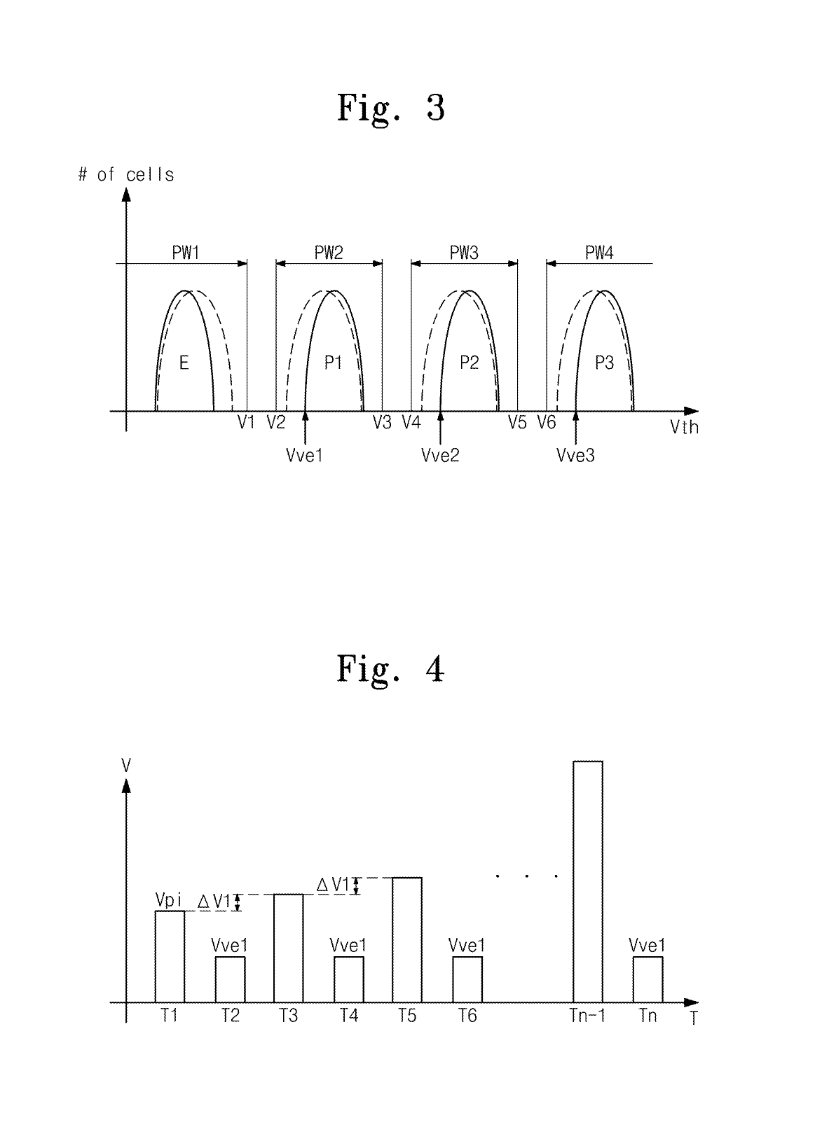

FIG. 3 illustrates threshold voltage distribution of memory cells of flash memory device 200 shown in FIG. 2. In FIG. 3, a horizontal axis denotes threshold voltages of memory cells and a vertical axis denotes the number of memory cells. Although an erase state “E” and first through third program states P1-P3 are shown as examples in FIG. 3, the logic states of memory cells are not limited to these states E and P1-P3. In general, memory cells can be programmed to two or more logic states.

The threshold voltages of erase state “E” and first through third program states P1-P3 are not limited to those shown in FIG. 3. For instance, in certain embodiments where flash memory device 200 is a NAND flash memory device, a threshold voltage corresponding to an erase state “E” is a negative voltage while threshold voltages corresponding to first through third program states P1-P3 are positive voltages. On the other hand, in certain embodiments where the flash memory device is a NOR flash memory device, threshold voltages corresponding to erase state “E” and first through third program states P1-P3 are positive voltages.

In FIG. 3, each solid curve represents threshold voltage distribution of normal memory cells and each dotted curve represents threshold voltage distribution of deteriorated memory cells. As illustrated in FIG. 3, the threshold voltage distributions of memory cells expand when memory cells are deteriorated. Such deterioration of memory cells can become worse as a program operation and an erase operation are performed.

A relationship between program and erase operations of flash memory device 200 and deterioration of memory cells will now be described below in further detail.

In certain embodiments where nonvolatile memory device 200 comprises a NAND flash memory device, a program operation comprises a bitline setup period and a wordline bias period. In the bitline setup period, bitlines are set up according to program data. For instance, a bitline corresponding to a memory cell to be programmed is set up with a ground voltage, and a bitline corresponding to a memory cell to be program-inhibited is set up with a program inhibit voltage, such as a power supply voltage.

In the wordline bias period, a pass voltage is applied to wordlines WL. The pass voltage is typically a voltage capable of turning on all memory cells connected to wordlines WL. Accordingly, where the pass voltage is applied to wordlines WL, a channel is formed through corresponding strings of memory cells. As a result, channels connected to bitlines set up with the ground voltage receive the ground voltage, and channels connected to bitlines set up with the program inhibit voltage receive the program inhibit voltage. A channel voltage of a string receiving the program inhibit voltage is boosted, and the channel voltage of a string connected to the ground voltage is floated. In other words, the channel of a program-inhibited memory cell is boosted, and a channel of a memory cell to be programmed is floated.

After the bitline and wordline bias periods, a program voltage Vpgm is applied to a selected wordline. A control gate voltage of a memory cell to be programmed receives program voltage Vpgm, and a channel of the memory cell receives the ground voltage. Consequently, Fowler-Nordheim (FN) occurs due to an electric field established between the control gate and the channel of the memory cell to be programmed, and charges migrate from the channel to a charge storage layer of the memory cell through a tunneling dielectric layer. The charges are thus accumulated or trapped in the charge storage layer.

The channel voltages of program-inhibited memory cells are boosted. Accordingly, an electric field established between control gates and channels of the program-inhibited memory cells is not strong enough to cause FN tunneling. Thus, the program-inhibited memory cells are not programmed.

In certain embodiments where nonvolatile memory device 200 comprises a NOR flash memory device, a program operation comprises a wordline bias period and a bitline bias period. In the wordline bias period, a selected wordline is biased to a program voltage Vpgm. In the bitline bias period, a selected bitline is biased with a bitline voltage. The bitline voltage is applied to a drain of a selected memory cell, and a source of the selected memory cell is maintained at a ground voltage.

Hot electrons are generated due to an electric field established between the drain and the source of the selected memory cell. The hot electrons are injected into a charge storage layer through a tunneling dielectric layer by an electric field transferred from the control gate of the selected memory cell. In other words, the selected memory cell is programmed by hot electron injection.

A program operation of flash memory device 200 is performed using incremental step pulse programming (ISPP). During the program operation, a program start voltage having a predetermined level is applied to a selected wordline. Thereafter, a verify voltage with a predetermined level is applied to the selected wordline. During application of the verify voltage, memory cells with threshold voltages higher than the verify voltage are turned off, and memory cells with threshold voltages lower than the verify voltage are turned on. The memory cells that are turned on are determined to be insufficiently programmed and are designated as “PROGRAM FAIL” cells. The memory cells that are turned-off determined to be successfully programmed and are designated as “PROGRAM PASS” cells.

The program operation is repeated until a memory cell to be programmed is determined to be “PROGRAM PASS”. That is, a program voltage Vpgm and a verify voltage are repeatedly applied to the memory cell to be programmed in numerous program loops until the memory cell is successfully programmed. Where the program operation is repeated, program voltage Vpgm increases in successive program loops, and a threshold voltage of the memory cell to be programmed tends to increase in proportion to the increment of program voltage Vpgm. That is, during ISPP, a threshold voltage of the memory cell to be programmed increases step by step in proportion to the increment of program voltage Vpgm.

In FIG. 3, “PROGRAM PASS” memory cells are indicated by solid curves. To achieve these curves, program operations are performed with verify voltages Vve1 through Vve3 for respective program states P1 through P3.

In certain embodiments where nonvolatile memory device 200 comprises a NAND flash memory device, an erase operation is performed by biasing wordlines WL and a well. For example, in one embodiment, wordlines WL are biased to a ground voltage and the well is biased to an erase voltage, where the erase voltage is a high voltage. At this point, FN tunneling occurs due to an electric field established between a control gate and a well of a memory cell. Consequently, charges migrate to the well through a tunneling dielectric layer from a charge storage layer of the memory cell.

In certain embodiments where nonvolatile memory device 200 comprises a NOR flash memory device, an erase operation is performed by biasing wordlines WL and a well. For example, in one embodiment, wordlines WL are biased to a predetermined negative voltage (e.g., wordline voltage) and the well is biased to a predetermined positive voltage (e.g., erase voltage). At this point, FN tunneling occurs due to an electric field established between a control gate and a well of a memory cell. Consequently, charges migrate to the well through a tunneling dielectric layer from a charge storage layer of the memory cell.

In the above embodiments, stress is applied to memory cells when they are programmed or erased. Such stress can be caused by a high voltage applied to the memory cells, and charges passing through the memory cells' tunneling dielectric layers. Where the charges pass the tunneling dielectric layers of memory cells, the tunneling dielectric layers can be deteriorated. That is, dielectric characteristics of the tunneling dielectric layers can be weakened. In addition, where the charges pass the tunneling dielectric layers of memory cells, the charges can be trapped in the tunneling dielectric layers. Where the charges are trapped in the tunneling dielectric layers, dielectric characteristics of the tunneling dielectric layers can be weakened.

Where the memory cells are deteriorated, their retention characteristics tend to be degraded. Accordingly, charged accumulated, injected or trapped to charge storage layers of the memory cells can be lost from the memory cells. In certain embodiments, where the number of positive charges is greater than that of negative charges at the charge storage layers of the memory cells, the positive charges can be lost. On the other hand, where the number of positive charges is smaller than that of negative charges at the charge storage layers of the memory cells, the negative charges can be lost.

Where charges are lost from the memory cells, their threshold voltages change. Moreover, the threshold voltages of the memory cells can change even after a program operation is completed. In general the loss of charges from a memory cell subsequent to programming is called “charge loss”.

In FIG. 3, dotted curves indicate the results of charge loss on the threshold voltage distributions of programmed memory cells in first through third program states P1-P3. The threshold voltage distributions of memory cells in first through third program states P1-P3 can expand beyond the corresponding verify voltages as indicated in FIG. 3. Threshold voltage distributions of memory cells in erase state “E” can also expand as indicated by a dotted curve in FIG. 3.

To compensate for the expansion of threshold voltage distributions due to charge loss, flash memory device 200 sets a read pass window. A first pass window PW1 is set to encompass a threshold voltage distribution corresponding to erase state “E”. First pass window PW1 encompasses a wider voltage range than the threshold voltage distribution corresponding to erase state “E”. First pass window PW1 is set such that the threshold voltage distribution of memory cells in erase state “E” falls within first pass voltage window PW1 in spite of deterioration of memory cells.

During a read operation, it is determined that memory cells having a threshold voltage corresponding to first pass window PW1 are in erase state “E”. Thus, read errors can be prevented from occurring despite deterioration of the memory cells. In the example of FIG. 3, first pass window PW1 spans a voltage region delimited by a first voltage V1.

Similarly, a second pass window PW2 is set to include a threshold voltage corresponding to first program state P1. Second pass window PW2 is set such that the threshold voltage distribution of the memory cells in first program state P1 fall within second pass window PW2 in spite of deterioration of memory cells. During a read operation, it is determined that memory cells having a threshold voltage within second pass window PW2 are in first program state P1. In the example of FIG. 3, second pass window PW2 corresponds to a voltage region between second and third voltages V2 and V3.

Third and fourth pass windows PW3 and PW4 are set in a similar manner to first and second pass windows PW1 and PW2. In this example, third pass window PW3 corresponds to a voltage region between fourth and fifth voltages V4 and V5 and fourth pass window PW4 corresponds to a voltage region being equal to or higher than a sixth voltage V6. During a read operation, it is determined that memory cells having a threshold voltage within third pass window PW3 are in second program state P2, and memory cells having a threshold voltage within fourth pass window PW4 are in third program state P3.

In the above examples, read operations are performed such that memory cells having threshold voltages corresponding to the first through fourth pass windows PW1-PW4 are determined to be in erase state “E” and first through third states P1-P3, respectively. Accordingly, read voltages can be set in the margins between voltages V1 and V2, between voltages V3 and V4, and between voltages V5 and V6.

Threshold voltage distributions of undeteriorated memory cells tend to remain the same after program operations, while threshold voltage distributions of deteriorated memory cells expand after program operations. Memory cells having threshold voltages within read pass windows (e.g., first through fourth pass windows PW1-PW4) are read normally. That is, where a read operation is performed using read pass windows, deteriorated memory cells are read without errors due to the expansion of threshold voltage distributions.

Nonvolatile memory device 200 controls program conditions depending on the degree of deterioration of selected memory cells. For instance, in certain embodiments, bias conditions of programming operations can be adjusted to account for the deterioration. The bias conditions can also be adjusted to improve the programming speed of undeteriorated memory cells. Hereinafter, a program operation for deteriorated memory cells will be referred to as a normal program operation and a program operation for undeteriorated memory cells will be referred to as a fast program operation.

In certain embodiments, deterioration of memory cells is determined with reference to a number of program/erase cycles that have been performed on the memory cells. In the description that follows, a number of program/erase cycles sufficient to cause deterioration of memory cells will be referred to as a “deterioration cycle”. In other words, once the number of program/erase cycles of selected memory cells equals or exceeds a deterioration cycle, the selected memory cells are deemed to be deteriorated. On the other hand, where the number of program/erase cycles of the selected memory cells is less than a deterioration cycle, the selected memory cells are deemed not to be deteriorated. The deterioration cycle typically corresponds to a predetermined value. The predetermined value can be determined, for instance, by measuring changes in threshold voltage distributions as a function of increased numbers of program/erase cycles.

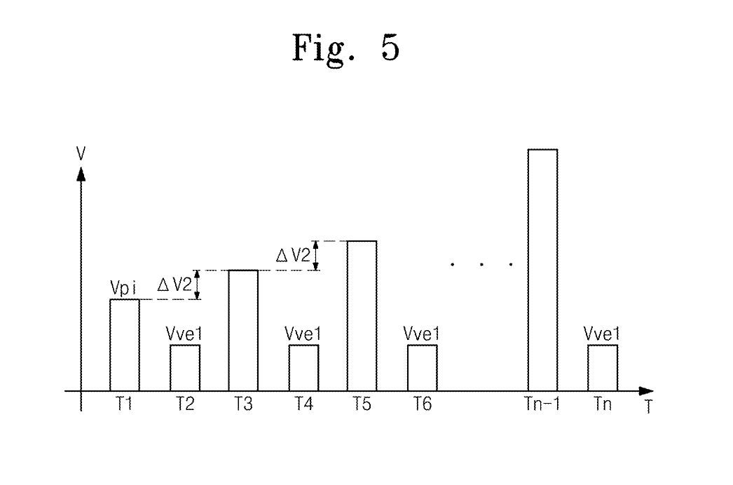

FIG. 4 illustrates a normal program operation of flash memory device 200 shown in FIG. 2. In FIG. 4, a horizontal axis represents time and a vertical axis represents voltages applied to a selected wordline connected to selected memory cells to be programmed.

Referring to FIGS. 2 and 4, at a first time T1, a program voltage Vpgm is applied to the selected wordline with a predetermined value. In this example, the predetermined value is a program start voltage Vpi.

At a second time T2, first verify voltage Vve1 is applied to the selected wordline for a program verify operation. First verify voltage Vve1 corresponds to first program state P1 shown in FIG. 3. However, the verify voltage is not limited to first verify voltage Vve1. The verify voltage can be one of first through third verify voltages Vve1-Vve3. That is, the program method of FIG. 4 can be applied to program operations where the selected memory cells are programmed to first through third program states P1-P3.

At a third time T3, program voltage Vpgm is applied to the selected wordline with a value increased by ΔV1 relative to program start voltage Vpi. At a fourth time T4, first verify voltage Vve1 is again applied to the selected wordline for a program verify operation.

At a fifth time T5, program voltage Vpgm is applied to the selected wordline with a value increased by ΔV1 relative to third time T3. At a sixth time T6, first verify voltage Vve1 is again applied to the selected wordline for a program verify operation.

At subsequent times up until a time Tn, program voltage Vpgm and first verify voltage Vve1 are repeatedly applied to the selected wordline while program voltage Vpgm increases by first voltage difference ΔV1 with each repetition.

FIG. 5 illustrates a fast program operation of flash memory device 200 shown in FIG. 2. In FIG. 5, a horizontal axis represents time and a vertical axis represents voltages applied to a wordline.

Referring to FIGS. 2 and 5, at a first time T1, a program voltage Vpgm is applied to a selected wordline connected to selected memory cells to be programmed. Program voltage Vpgm applied to the selected wordline at first time T1 has program start voltage Vpi. At a second time T2, first verify voltage Vve1 is applied to the selected wordline to perform a program verify operation. Although FIG. 5 illustrates first verify voltage Vve1, other verify voltage levels can be used to program the selected memory cells to states other than program state P1.

At third time T3, a program voltage Vpgm is applied to the selected wordline. At fourth time T4, first verify voltage Vve1 is again applied to the selected wordline to perform a program verify operation. Program voltage Vpgm applied at third time T3 has a higher level than program voltage Vpgm applied at first time T1. Between times T1 and T3, program voltage Vpgm is incremented by a second voltage difference ΔV2.

At fifth time T5, program voltage Vpgm is applied to the selected wordline. At sixth time T6, first verify voltage Vve1 is again applied to the selected wordline to perform a program verify operation. Program voltage Vpgm applied at the fifth time T5 has have a level that increases by first voltage difference ΔV2 compared with program voltage Vpgm applied at third time T3. Moreover, program voltage Vpgm and first verify voltage Vve1 are repeatedly applied to the selected memory cells in successive program loops while program voltage Vpgm increases by the first voltage difference ΔV2.

Referring to FIGS. 4 and 5, an increment of program voltage Vpgm for a normal program operation is a first voltage difference ΔV1, and an increment of program voltage Vpgm for a fast program operation is a second voltage difference ΔV2. Second voltage difference ΔV2 is greater than first voltage difference ΔV1.

Since second voltage difference ΔV2 is greater than first voltage difference ΔV1, the threshold voltage fluctuation amount of fast programmed memory cells tends to be greater than that of normally programmed memory cells. A threshold voltage of the fast programmed memory cells can reach a verify voltage Vve1 earlier than that of the normally programmed memory cells. In other words, program speed of the fast program operation is higher than that of the normal program operation.

A threshold voltage distribution of the fast programmed memory cells may be greater than that of the normally programmed memory cells. However, as described with reference to FIG. 3, read pass windows (e.g., first through fourth pass windows PW1-PW4) have a margin for compensating for deterioration of memory cells. Accordingly, where a threshold voltage distribution of memory cells expands due to the fast program operation, the memory cells can be normally read if a program voltage Vpgm (or an increment of program voltage Vpgm) is controlled such that the threshold voltage distribution of the memory cells is included within second pass window PW2.

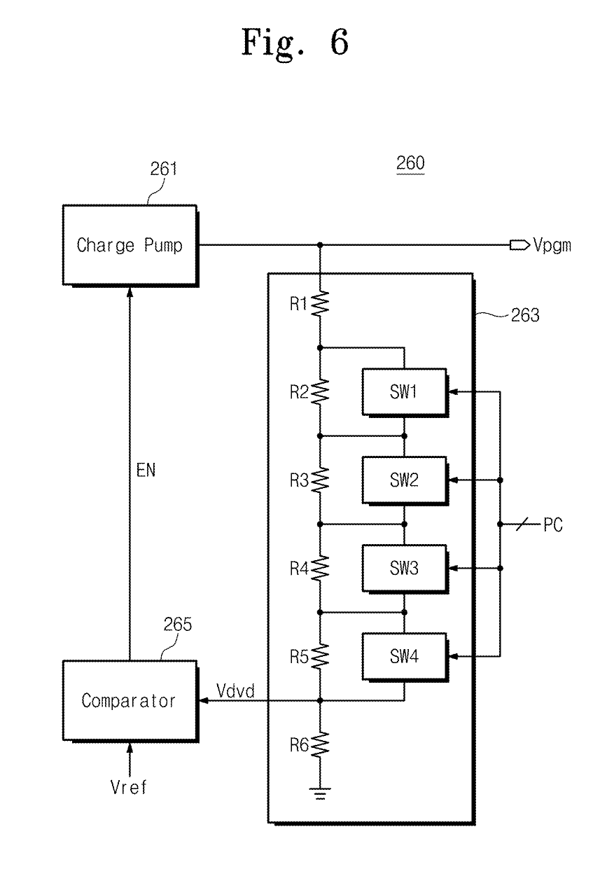

FIG. 6 is a block diagram illustrating an example of program voltage generator 260 shown in FIG. 2. As illustrated in FIG. 6, program voltage generator 260 comprises a charge pump 261, a divider 263, and a comparator 265.

Charge pump 261 is configured to perform a pumping operation in response to an enable signal EN. An output of charge pump 261 is used as a program voltage Vpgm.

Divider 263 is configured to generate a divided voltage by dividing program voltage Vpgm. In the example of FIG. 6, divider 263 comprises first through sixth resistors R1-R6 and first through fourth switches SW1-SW4.

First through sixth resistors R1-R6 are connected in series, and first through fourth switches SW1-SW4 are connected in parallel to respective second through fifth resistors R2-R5. First through fourth switches SW1-SW4 are turned on and turned off in response to a program control signal PC. Where first switch SW1 is turned on, current flows through first switch SW1 and bypasses second resistor R2. In other words, where first switch SW1 is turned on, second resistor R2 is disregarded. Similarly, where second through fourth switches SW2-SW4 are turned on, respective third through fifth resistors R3-R5 are disregarded.

A voltage between fifth and sixth resistors R5 and R6 is transferred to comparator 265 as a divided voltage Vdvd.

Comparator 265 receives divided voltage Vdvd from divider 263 and also receives a reference voltage Vref. Comparator 265 compares divided voltage Vdvd with reference voltage Vref to activate or deactivate enable signal EN. Where divided voltage Vdvd is lower than reference voltage Vref, comparator 265 activates enable signal EN. Where divided voltage Vdvd is greater than or equal to reference voltage Vref, comparator 265 deactivates enable signal EN. In other words, comparator 265 drives charge pump 261 until a level of divided voltage Vdvd reaches a level of reference voltage Vref.

By adjusting the number of switches SW1-SW4 turned on by program control signal PC, the number of disregarded resistors among second through fifth resistors R2-R5 is adjusted. Accordingly, a ratio of the divided voltage Vdvd to a program voltage Vpgm is adjusted by controlling program control signal PC.

There may be a difference between levels of the programs voltage Vpgm before and after adjusting program control signal PC. That is, control logic 240 is configured to adjust a level of program voltage Vpgm by controlling program control signal PC. ISPP can then be executed using the adjusted program voltage Vpgm.

In certain embodiments, the voltage generator comprises two program voltage generators 260 for a normal program operation and a fast program operation. One program voltage generator can increment program voltage Vpgm by first voltage difference ΔV1, and the other program voltage generator can increment program voltage Vpgm by second voltage difference ΔV2. Control logic 240 can select one of the two program voltage regulators 260, depending on the degree of deterioration degree in selected memory cells. Information for selecting voltage generators can be incorporated in program control signal PC.

In normal and fast program operations, control logic 240 adjusts the number of switches SW1-SW4 that are switched on at the same time. For instance, control logic 240 can control one switch to be turned on or off at one time during a normal program operation, and then control two switches to be turned on or off at one time during a fast program operation.

Resistances of resistors R1-R6 can be designed based on the requirements of normal and fast program operations. For instance, resistors corresponding to switches turned on and turned off during the fast program operation can be set to have greater resistances than those corresponding to switches turned on and turned off during the normal program operation.

Program voltage generator 260 functions to adjust a level of program voltage Vpgm by the unit of first voltage difference ΔV1 or second voltage difference ΔV2. The structure of program voltage generator 260 is not limited thereto, and could be modified in alternative embodiments. For instance, various changes could be made to program voltage generator 260 as follows. Pairs of the second to fifth resistors R2-R5 corresponding to first through fourth switches SW1-SW4 could be connected in parallel. A divided voltage Vdvd could be output to a node other than a node between the fifth and sixth resistors R5 and R6. Enable signal of comparator 265 could be a clock signal for driving charge pump 261. Flash memory device 200 could further include a decoder configured to decode program control signal PC provided from control logic 240. The number of resistors and switches of divider 263 could be varied.

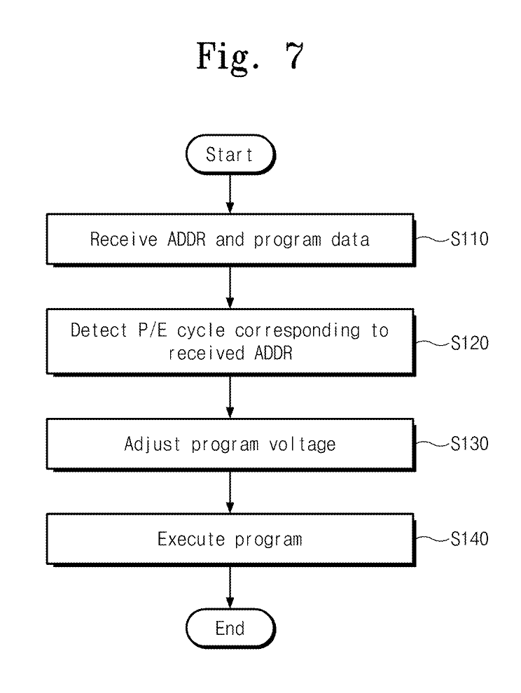

FIG. 7 is a flowchart illustrating a program operation of flash memory device 200 shown in FIG. 2. In the description that follows, example method steps are denoted by parentheses (SXXX).

Referring to FIGS. 2, 6, and 7, program data and an address ADDR are received (S110). In certain embodiments, program data and an address ADDR are received from controller 100 shown in FIG. 1. The program data is loaded to read and write circuit 230, and address ADDR is provided to address decoder 220.

Thereafter, program and erase cycle corresponding to the received address ADDR is detected (S120). In certain embodiments, control logic 240 makes reference to address ADDR stored in an address buffer (not shown) of address decoder 220. The number of program and erase cycles of a storage area corresponding to address ADDR can be detected with reference to address ADDR. In various alternative embodiments, the number program and erase cycles can be managed in page units, sector units, or in the basic unit of erasure (e.g., memory block, page, sector, etc.).

In certain embodiments, data regarding the numbers of program and erase cycles is maintained in memory cell array 210. For instance, memory cell array 210 can include a plurality of storage areas, and an erase operation can be performed in units of storage area. Each of the storage areas can include a spare area. Program and erase cycle of each of the storage areas can be stored in a corresponding spare area.

In certain embodiments, when an address ADDR and program data are received, control logic 240 may control read and write circuit 230 such that program and erase cycle corresponding to the address ADDR is read out of a spare area.

In certain embodiments, at the time of power-on of flash memory device 200, control logic 240 controls read and write circuit 230 such that data regarding the number of program and erase cycles are read out of a spare area or spare areas. The read-out erase and program cycles can be stored in a storage element such as a latch, a register, and a buffer. Where address ADDR and the program data area received, control logic 240 can then reference the storage element to determine a number of program and erase cycles performed at the address.

In certain embodiments, the program and erase cycle of memory cell array 210 are be stored in a nonvolatile storage area other than memory cell array 210.

Subsequently, a program voltage Vpgm is adjusted (S130). Program voltage Vpgm is typically adjusted depending on whether memory cells are deteriorated. For instance, program voltage Vpgm, or an increment of program voltage Vpgm can be adjusted according to the detected program and erase cycle. Where the detected number of program and erase cycles is smaller than a deterioration cycle, the increment of program voltage Vpgm is set to a second voltage difference ΔV2. Where the detected program and erase cycle is greater than the deterioration cycle, the increment of program voltage Vpgm is set to first voltage difference ΔV1.

In certain embodiments, as described with reference to FIG. 6, control logic 240 controls program voltage Vpgm to regulate the increment of program voltage Vpgm.

After the adjustment of program voltage Vpgm, a program is executed (S140). Where the number of program and erase cycles of selected memory cells being programmed is smaller than the deterioration cycle, i.e., the selected memory cells are not deteriorated, a fast program is performed. Otherwise, where the number of program and erase cycles is greater than a deterioration cycle, i.e., the selected memory cells are deteriorated, a normal program is executed.

As indicated by the foregoing, flash memory device 200 adjusts a program voltage Vpgm depending on the degree of deterioration of selected memory cells. More specifically, flash memory device 200 can control an increment of a program voltage Vpgm depending on a deterioration degree of memory cells. This makes it possible to prevent read errors caused by charge loss and improve program speed.

In the embodiment of FIG. 7, control logic 240 detects the number of program and erase cycles of selected memory cells based on a received address ADDR. However, the program and erase cycle can also be provided from an external source. For instance, the program and erase cycles can be provided from controller 100 shown in FIG. 1.

In certain embodiments, flash memory device 200 reads the number of program and erase cycles from memory cell array 210 at the time of power-on. The read-out program and erase cycles can then be transmitted to controller 100 so that controller 100 can manage the received program and erase cycles.

Where a program or erase operation of flash memory device 200 is performed, controller 100 monitors the number of program and erase cycles. Where memory system 10 is powered off, controller 100 writes the number of program and erase cycles in flash memory device 200. In other words, in some embodiments, flash memory device 200 stores information regarding program and erase cycles and controller 100 manages the information regarding program and erase cycles.

In certain embodiments, software driven by controller 100 manages the information regarding program and erase cycles. For instance, a flash translation layer (FTL) driven by controller 100 can manage the program and erase cycles.

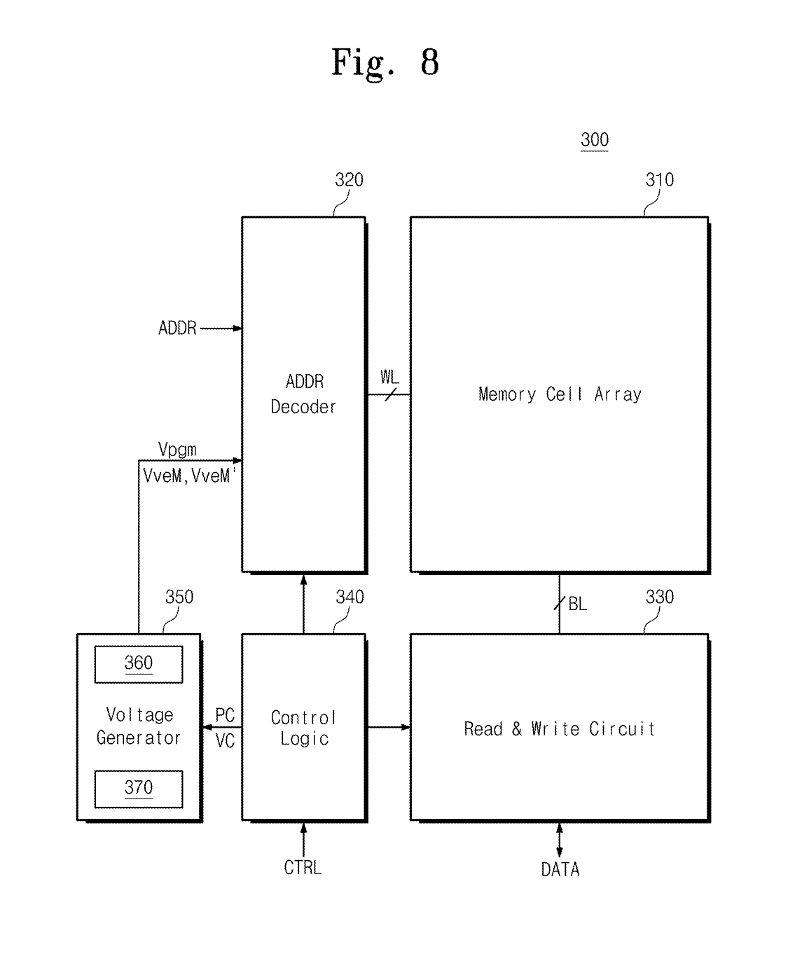

FIG. 8 is a block diagram illustrating an alternative embodiment of flash memory device 200 shown in FIG. 1.

Referring to FIG. 8, a flash memory device 300 comprises a memory cell array 310, an address decoder 320, a read and write circuit 330, control logic 340, and a voltage generator 350.

Memory cell array 310, address decoder 320, and read and write circuit 330 have substantially the same configuration as memory cell array 210, address decoder 220, and read and write circuit 230, respectively. Accordingly, a further description of memory cell array 310, address decoder 320, and read and write circuit 330 will be omitted to avoid redundancy.

Control logic 340 is configured to control the operation of flash memory device 300. Control logic 340 is configured to provide a program control signal PC and a verify control signal VC to a voltage generator 350.

Voltage generator 350 is configured to generate voltages required for driving flash memory device 300. Voltage generator 350 comprises a program voltage generator 360 and a verify voltage generator 370.

Control logic 340 and voltage generator 350 are configured similar to control logic 240 and voltage generator 250 of FIG. 2, except that control logic 340 provides verify control signal VC to voltage generator 350 and voltage generator 350 further comprises a verify voltage generator 370.

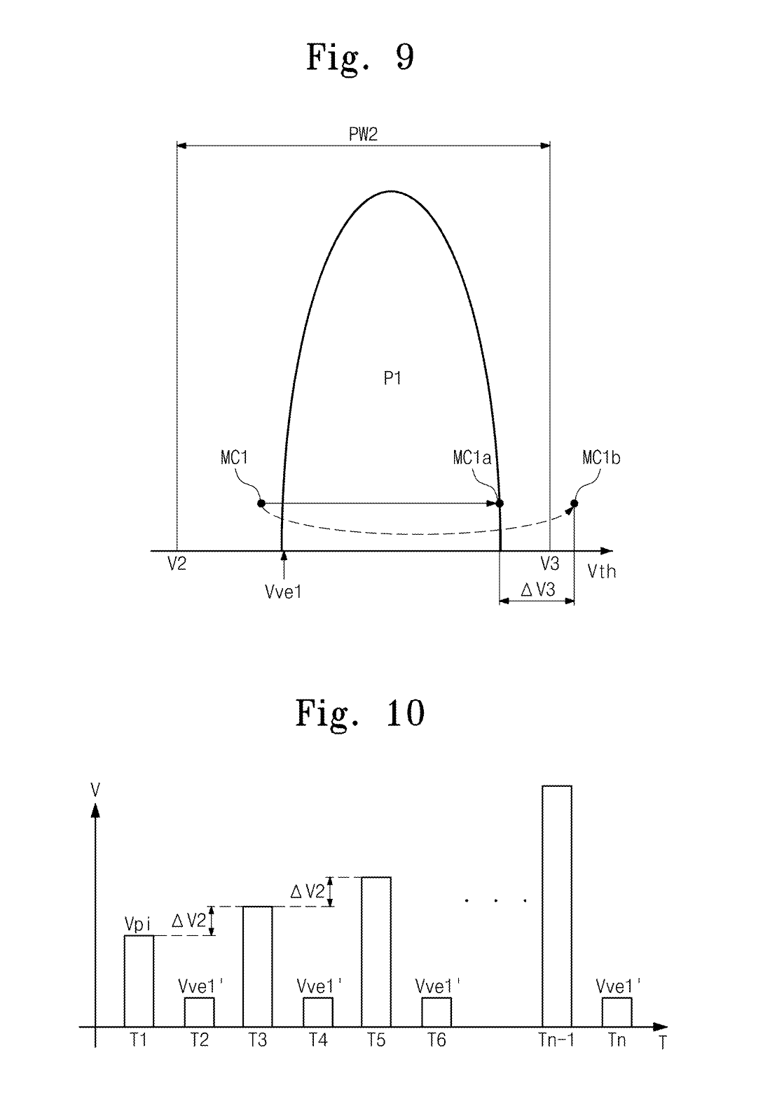

FIG. 9 illustrates threshold voltage distributions of memory cells programmed by flash memory device 200 shown in FIG. 2. In FIG. 9, a horizontal axis represents a threshold voltage of memory cells and a vertical axis represents the number of memory cells. In the example of FIG. 9, the threshold voltage distribution corresponds to first program state P1 shown in FIG. 3.

As illustrated in FIG. 3, charge loss can cause threshold voltage distributions to shift in different directions. For instance, threshold voltage distributions corresponding to first through third program states P1-P3 can expand in a low voltage level direction to the left in the graph of FIG. 9, or in a high level direction to the right in the graph of FIG. 9. Accordingly, a read pass window, such as a second pass window PW2 shown in FIG. 9, can be set to compensate for shifting of threshold voltage distributions in different directions. In second pass window PW, a first margin is provided in voltage region higher than the threshold voltage distribution and a second margin greater than the first margin is provided in a voltage region lower the threshold voltage distribution.

In the example of FIG. 9, it is assumed that a normal program operation is being performed. For instance, it is assumed that program voltage Vpgm is applied to a selected wordline in i−1 program loops. It is assumed that a first memory cell MC1 has a threshold voltage lower than a first verify voltage Vve1. Where an i^{th} program loop is performed with program voltage Vpgm, first memory cell MC1 is determined to be in a program pass state.

The threshold voltage of first memory cell MC1a after the i^{th} program loop can be determined according to a threshold voltage of first memory cell MC1 before applying the i^{th} program voltage Vpgm. For instance, where first memory cell MC1 has a threshold voltage of a level close to verify voltage Vve1, the threshold voltage of first memory cell MC1a may have a similar level to a maximum value of a threshold voltage distribution following the i^{th} program loop.

It is assumed that a fast program operation is performed under the same condition as the normal program operation. In particular, it is assumed that first memory cell MC1 is determined to be program passed following an i^{th} program loop. In the fast program operation, however, the increment of program voltage Vpgm in successive program loops is second voltage difference ΔV2, and an increment of program voltage Vpgm for the normal program operation is first voltage difference ΔV1, which is smaller than second voltage difference ΔV2. The difference between second voltage difference ΔV2 and first voltage difference ΔV1 is defined as a third voltage difference ΔV3.

A threshold voltage of fast-programmed memory cells varies according to the value of second voltage difference ΔV2, while a threshold voltage of normally-programmed memory cells varies based on a value of first voltage difference ΔV1. The degree of threshold voltage fluctuation of fast-programmed memory cells is greater than that of normally-programmed memory cells in proportion to third voltage difference ΔV3.

In second pass window PW2, a margin of a voltage region higher than a threshold voltage distribution is smaller than a margin of a voltage region lower than the threshold voltage distribution. Accordingly, where an i^{th} program voltage Vpgm is applied to selected memory cells being programmed to state P1 as in FIG. 9, a threshold voltage of a first memory cell MC1b may rise to a level beyond second pass window PW2 due to third voltage difference ΔV3. Where the threshold voltage of first memory cell MC1B rises to the level beyond second pass window PW2, a read error may occur.

To address the above problem, flash memory device 300 can adjust verify voltage Vve1 for fast program operations, while performing normal program operations in the same manner as flash memory device 200 described with reference to FIGS. 2 to 7. As illustrated in FIG. 10, a fast program operation of flash memory device 200 can be performed using a first verify voltage Vve1′ with a lower level than first verify voltage Vve1. For simplicity of description, first verify voltage Vve1 during a normal program operations and first verify voltage Vve1′ during a fast program operation will be referred to as a first normal verify voltage and a first fast verify voltage, respectively.

FIG. 10 illustrates a fast program operation of flash memory device 300 shown in FIG. 8. In FIG. 10, a horizontal axis represents time T and a vertical axis represents a voltage V applied to a selected wordline. Referring to FIGS. 5 and 10, the fast program operation of flash memory device 300 is performed using first fast verify voltage Vve1′ lower than first normal verify voltage Vve1.

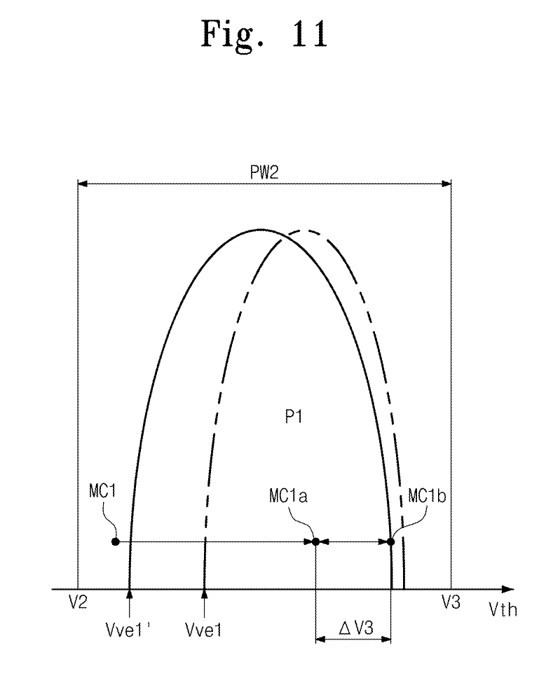

FIG. 11 illustrates threshold voltage distribution of memory cells programmed by flash memory device 300 shown in FIG. 8. In FIG. 11, a horizontal axis represents a threshold voltage Vth of memory cells and a vertical axis represents the number of memory cells. In FIG. 11, a dotted curve represents threshold voltage distribution generated by a normal program operation and a solid curve represents threshold voltage distribution generated by a fast program operation.

In the example of FIG. 11, it is assumed that first memory cell MC1 is fast programmed. It is further assumed that first memory cell MC1 assumes the program pass state following an i^{th} program loop.

An increment of program voltage Vpgm during the fast program operation is greater than an increment of program voltage Vpgm during the normal program operation by third voltage difference ΔV3. That is, the degree of threshold voltage fluctuation of a fast-programmed first memory cell MC1b is greater than that of a normally-programmed first memory cell MC1a by an amount proportional to third voltage difference ΔV3.

The level of first fast verify voltage Vve1′ is lower than that of first normal verify voltage Vve1, and a difference between first fast verify voltage Vve1′ and a third voltage V3 is greater than a difference between the first normal verify voltage Vve1 and third voltage V3. Thus, the threshold voltage of first memory cell MC1b falls within second pass window PW2 even though the degree of threshold voltage fluctuation of first memory cell MC1b increases more than memory cell MC1a in a normal program operation. As a result, where first fast verify voltage Vve1′ lower than first normal verify voltage Vve1 is used during the fast program operation, a read error can be prevented.

In certain embodiments, where a difference between increments of a program voltage Vpgm during normal and fast program operations is a third voltage difference ΔV3, a difference between first normal verify voltage Vve1 and first fast verify voltage Vve1′ is also set to third voltage difference ΔV3. For instance, first fast verify voltage Vve1′ can be set to be lower than first normal verify voltage Vve1 by third voltage difference ΔV3.

Fast program is used to program undeteriorated memory cells. Charge loss tends to be less pronounced in undeteriorated memory cells compared with deteriorated cells. In other words, charge loss in undeteriorated memory cells typically does not result in expansion of threshold voltage distributions. Thus, read errors from charge loss are prevented.

In certain embodiments, verify voltage generator 370 shown in FIG. 8 comprises separate verify voltage generators for generating first normal verify voltage Vve1 and first fast verify voltage Vve1′. Information for selecting the verify voltage generators can be incorporated in a verify control signal VC.

In certain embodiments, verify voltage generator 370 has the same structure as verify voltage generator 270 described with reference to FIG. 6. In such embodiments, an output of a charge pump is used as first normal verify voltage Vve1 and first fast verify voltage Vve1′. Verify control signal VC can turn on and off switches of a divider of verify voltage generator 370. Verify voltage generator 370 can be configured to output first verify voltage Vve1 or first fast verify voltage Vve1′ according to the turning on or off of the switches. Similar to the description made with reference to FIG. 6, the structure of verify voltage generator 370 is not limited to that shown, and could be varied in alternative embodiments.

In FIGS. 8 through 11, a fast program operation illustrated for first program state P1. It will be appreciated that the fast program operation can be similarly applied to second and third program states P2 and P3.

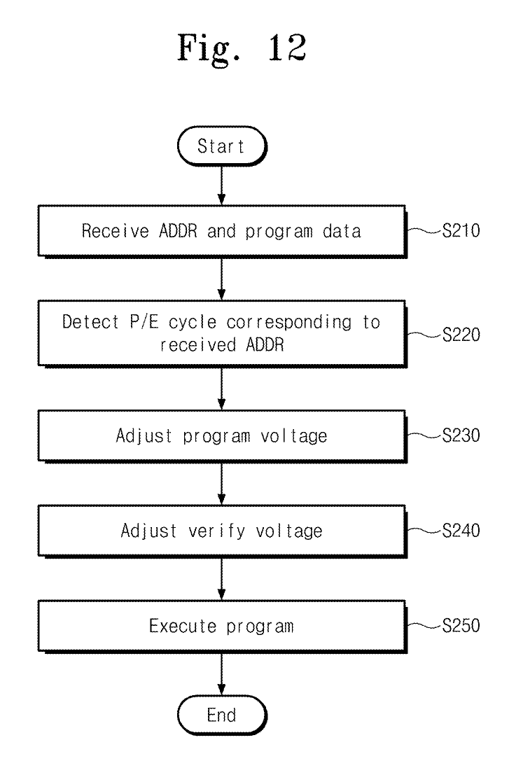

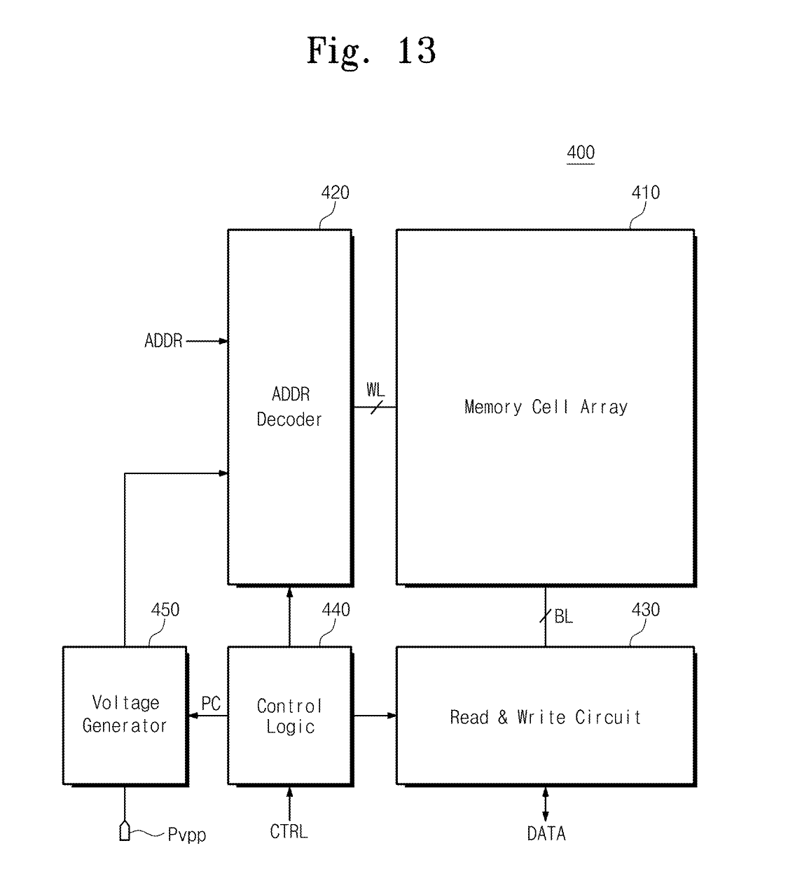

FIG. 12 is a flowchart illustrating a program operation of flash memory device 300 shown in FIG. 8.

Referring to FIGS. 8 and 12, an address ADDR and program data are received by flash memory device 300 (S210). This may be accomplished similar to step S110 of FIG. 7. Thereafter, the number of program and erase cycles corresponding to address ADDR is detected. This can be accomplished similar to step S120 of FIG. 7. Then, a program voltage Vpgm is adjusted (S230). This can be accomplished similar to step S130 of FIG. 7.

Next, a verify voltage is adjusted (S240). Where the number of detected program and erase cycles is greater than the deterioration cycle, a normal verify voltage is selected. On the other hand, where the detected number of program and erase cycles is smaller than the deterioration cycle, a fast verify voltage is selected. Control logic 340 provides verify control signal VC to voltage generator 350 to select a normal verify voltage or a fast verify voltage.

Subsequently, a program is executed (S250). In certain embodiments, where the number of detected program and erase cycles is greater than the deterioration cycle, a normal program operation is executed. On the other hand, where the detected number of program and erase cycles is smaller than the deterioration cycle, a fast program operation is executed.

As indicated by the foregoing, flash memory device 300 performs a normal program operation or a fast program operation depending on the deterioration degree of memory cells. An increment of a program voltage Vpgm and a verify voltage are adjusted during the fast program operation. Thus, read errors due to charge loss and read errors caused by adjustment of program voltage Vpgm can be prevented and programming speed can be improved.

In the embodiment of FIG. 12, the number of program and erase cycles is detected by control logic 340. However, in alternative embodiments, as described with reference to FIG. 8, the number of program and erase cycles can be provided from controller 100.

FIG. 13 is a block diagram illustrating another alternative embodiment of flash memory device 200 shown in FIG. 1. Referring to FIG. 13, a flash memory device 400 comprises a memory cell array 410, an address decoder 420, a read and write circuit 430, control logic 440, and a voltage generator 450.

Memory cell array 410, address decoder 420, and read and write circuit 430 are configured with substantially the same structures as memory cell array 210, address decoder 220, and read and write circuit 230 described with reference to FIGS. 2 through 7, respectively.

Control logic 440 is configured to control the operation of flash memory device 400.

Voltage generator 450 is configured to generate voltages used to drive flash memory device 400. Voltage generator 450 is connected to a high voltage terminal Pvpp configured to receive a high voltage Vpp.

Where high voltage Vpp is received through the high voltage terminal Pvpp, flash memory device 400 operates in an acceleration mode. In the acceleration mode, flash memory device 400 executes a program using the high voltage Vpp received through high voltage terminal Pvpp.

Flash memory device 400 is a NOR flash memory device. During a program operation, current flows to a source line from bitlines BL of NOR flash memory device 400 through a selected memory cell. Because current flows through bitlines BL, NOR flash memory device 400 consumes power during a program operation. Due to a limitation on capacity of a pump in NOR flash memory device 400, there is a limitation on number of memory cells (or bits) that can be programmed at the same time.

Where high voltage Vpp is received through high voltage terminal Pvpp, NOR flash memory device 400 biases bitlines BL using high voltage Vpp. In other words, the power for a program operation is externally supplied through high voltage terminal Pvpp. Since the program operation is performed using external power, a larger number of memory cells (or bits) can be programmed at the same time. Consequently, flash memory device 400 is configured to perform an acceleration mode where program speed is improved using external power.

In certain embodiments, the acceleration mode is performed where the number of program and erase cycles of a selected region of memory cell array 410 is smaller than a predetermined value (hereinafter referred to as “acceleration cycle”). Where the number of program and erase cycles is greater than the acceleration cycle, the acceleration mode is not performed.

The acceleration cycle can be used as a reference value for performing normal and fast program operations described with reference to FIGS. 2 through 11. In certain embodiments, where the number of program and erase cycles is smaller than the acceleration cycle, flash memory device 400 performs a fast program operation. Otherwise, where the number of program and erase cycles is greater than the acceleration cycle, flash memory device 400 performs a normal program operation.

When the number of program and erase cycles is smaller than the acceleration cycle, flash memory device 400 operates in the acceleration mode to perform the fast program operation. Accordingly, the program speed of the acceleration mode of flash memory device 400 may be improved.

In certain embodiments, device information is stored in flash memory device 400 during manufacture. The device information can be programmed in flash memory device 400 using a fast program operation in an acceleration mode.

In certain embodiments, where a product is manufactured with flash memory device 400, various types of data can be stored in flash memory device 400. For instance, information on a product, code and firmware for driving the product, and an operating system and applications to be driven in the product may be stored in flash memory device 400. In such embodiments, flash memory device 400 can program the data using a fast program operation in an acceleration mode.

By programming flash memory device 400 using the acceleration mode, the manufacturing speed of a product using flash memory device 400 can be improved.

In certain embodiments, voltage generator 450 comprises a program voltage generator. Control logic 440 typically provides a program control signal to voltage generator 450 for controlling the program voltage generator. Except for high voltage terminal Pvpp, control logic 440 and voltage generator 450 can be formed with substantially the same structures as control logic 240 and voltage generator 250 described with reference to FIGS. 2 through 7, respectively.

In certain embodiments, voltage generator 450 comprises a program voltage generator and a verify voltage generator. Control logic 440 provides a control signal for controlling the program voltage generator and a verify control signal for controlling the verify voltage generator to voltage generator 450. Except for high voltage terminal Pvpp, control logic 440 and voltage generator 450 can be organized with the same structures as control logic 340 and voltage generator 350 described with reference to FIGS. 8 through 12, respectively.

In the foregoing embodiments, flash memory devices 200, 300, and 400 are configured to adjust an increment of a program voltage. Moreover, flash memory devices 200, 300, and 400 can adjust an increment of a program voltage twice or more times depending on deterioration degree of memory cells.

In the foregoing embodiments, a program voltage is a voltage applied to a wordline during a program operation. However, the inventive concept is not limited to applying the program voltage to a wordline during a program operation. For instance, the program voltage can be applied to other parts of a memory device besides a wordline.

In the foregoing embodiments, a program voltage is adjusted depending on deterioration degree of memory cells. However, an erase voltage can also be adjusted depending on the deterioration degree of memory cells. In other words, certain voltage adjustment techniques described above can also be applied to erase operations.

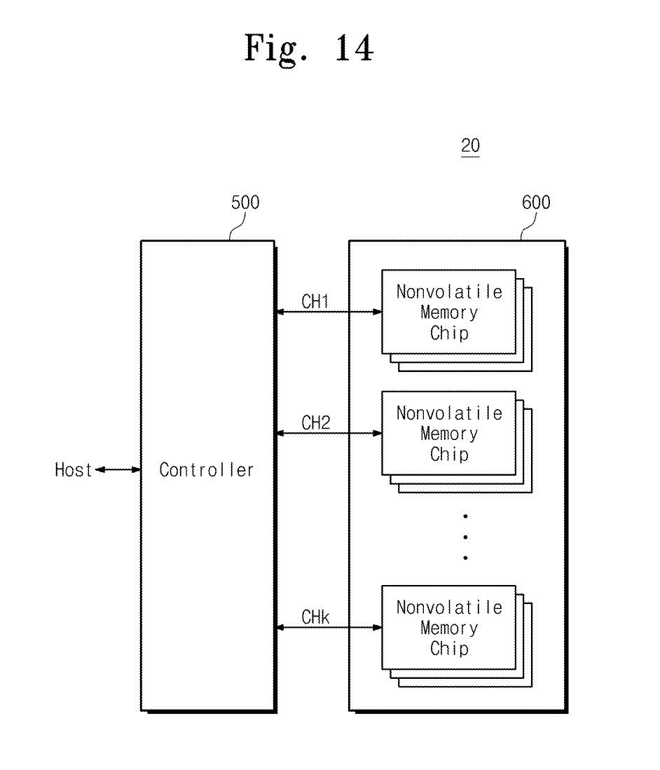

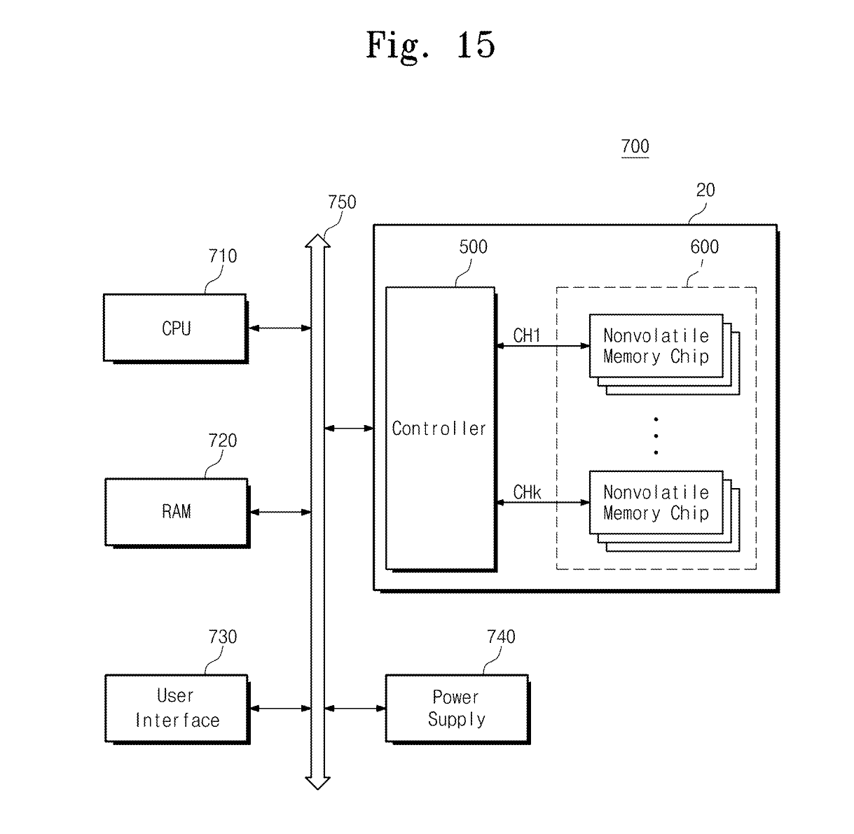

FIG. 14 is a block diagram illustrating an alternative embodiment of memory system 10 shown in FIG. 1. Referring to FIG. 14, a memory system 20 comprises a controller 500 and a nonvolatile memory device 600. Nonvolatile memory device 600 comprises a plurality of nonvolatile memory chips divided into a plurality of groups. Each of the groups of the nonvolatile memory chips is configured to communicate with controller 500 through a corresponding channel. In FIG. 14, it is shown that the nonvolatile memory chips communicate with controller 500 through first through k^{th} channels CH1-CHk. Each of the nonvolatile memory chips is organized with the same structure as flash memory device 200 described with reference to FIG. 2, flash memory device 300 described with reference to FIG. 300, or flash memory device 400 described with reference to FIG. 12.

FIG. 15 is a block diagram illustrating a computing system 700 comprising memory system 20 shown in FIG. 2. Referring to FIG. 15, computing system 700 comprises a central processing unit (CPU) 710, a random access memory (RAM) 720, a user interface 730, a power supply 740, and a memory system 20.

Memory system 20 is electrically connected to CPU 710, RAM 720, user interface 730, and power supply 740 through a system bus 750. Data provided through user interface 730 or processed by CPU 710 is stored in memory system 20. Memory system 20 comprises a controller 500 and a nonvolatile memory device 600.

In certain embodiments, nonvolatile memory device 600 comprises a plurality of nonvolatile memory chips, which may be divided into a plurality of groups. Each of the groups of the nonvolatile memory chips is configured to communicate with controller 500 through a common channel. In FIG. 15, the nonvolatile memory chips communicate with controller 500 through first through k^{th} channels CH1-CHk.

Where memory system 20 is an SSD, booting speed of computing system 500 may be improved significantly. Although not illustrated in the figures, computing system 500 can further comprises an application chipset, a camera image processor, or other features.

In certain embodiments, computing system 700 is incorporates memory system 10 described with reference to FIG. 1 instead of memory system 20 described with reference to FIG. 13.

In certain embodiments, computing system 700 may be configured to include the memory systems 10 and 20 described with reference to FIGS. 1 through 13. In this case, controllers 100 and 500 are connected to system bus 750.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

What is claimed is:

1. A method of performing a program operation on memory cells in a nonvolatile memory device, comprising:
determining a level of a program voltage based on a degree of deterioration of the memory cells; and
executing the program operation using the program voltage.

2. The method of claim 1, wherein the degree of deterioration is determined based on a number of program or erase cycles performed on the memory cells.

3. The method of claim 1, wherein the degree of deterioration is detected based on a number of program and erase cycles performed on the memory cells.

4. The method of claim 1, wherein determining the level of the program voltage comprises adjusting an increment of the program voltage to be applied between successive program loops of the program operation.

5. The method of claim 4, further comprising:
determining a level of a verify voltage for the program operation based on the increment of the program voltage.

6. The method of claim 4, further comprising:
determining a number of program or erase cycles performed on the memory cells;
setting the increment of the program voltage to a first value upon determining that the number of program or erase cycles is greater than a predetermined value, and
setting the increment of the program voltage to a second value greater than the first value upon determining that the number of program or erase cycles is less than or equal to the predetermined value.

7. The method of claim 6, further comprising:
setting a verify voltage for the program operation to a first level where the increment of the program voltage is set to the first value, and setting the verify voltage to a second level lower than the first level where the increment of the program voltage is set to the second value.

8. The method of claim 1, wherein the program operation is executed with a high voltage received from an external source depending on the degree of deterioration of the memory cells.

9. The method of claim 1, wherein the nonvolatile memory device is a multi-level cell flash memory device.

10. The method of claim 1, wherein the program operation is executed using incremental step pulse programming.

11. A nonvolatile memory device comprising:
a memory cell array;
a read/write circuit configured to perform program and read operations on the memory cell array;
a voltage generator configured to provide voltages to the memory cell array; and
control logic configured to control the read/write circuit and the voltage generator,
wherein the control logic controls the voltage generator to adjust a program voltage depending on a degree of deterioration of memory cells in the memory cell array.

12. The nonvolatile memory device of claim 11, wherein the degree of deterioration of the memory cells is detected based on a number of program and erase cycles that have been performed on the memory cells.

13. The nonvolatile memory device of claim 12, wherein the control logic stores the number of program and erase cycles that have been performed on the memory cells.

14. The nonvolatile memory device of claim 11, wherein the control logic is configured to program the memory cells using an acceleration mode wherein a high voltage supplied from an external source is provided to the memory cell based on the degree of deterioration of the memory cells.

15. The nonvolatile memory device of claim 11, wherein the control logic controls the read/write circuit to perform a program operation using incremental step pulse programming with the adjusted program voltage.

16. The nonvolatile memory device of claim 15, wherein the adjusted program voltage is incremented with a first or second increment in successive program loops of the program operation depending on a number of program or erase cycles that have been performed previously on the memory cells.

17. The nonvolatile memory device of claim 11, wherein the memory cell array comprises flash memory cells arranged in a NAND flash configuration.

18. A memory system comprising:
a nonvolatile memory device; and
a controller configured to control the nonvolatile memory device,
wherein the nonvolatile memory device comprises:
a memory cell array;
a read/write circuit configured to perform read and write operations on the memory cell array;
a voltage generator configured to provide voltages to the memory cell array; and
control logic configured to control the read and write circuit and the voltage generator,
wherein the control logic controls the voltage generator such that a program voltage is adjusted depending on a degree of deterioration of memory cells of the memory cell array.

19. The memory system of claim 18, wherein:
the nonvolatile memory device and the controller are incorporated in a solid-state drive (SSD).

20. The memory system of claim 18, wherein the control logic controls the voltage generator to adjust a program verify voltage based on a number of program or erase operations that have been performed previously on selected memory cells to be programmed in a program operation.
